(19) United States
(12) Patent Application Publication
(10) Pub. No.: US 2009/0146284 A1
(43) Pub. Date: Jun. 11, 2009

(54) Molded Leadless Packages and Assemblies Having Stacked Molded Leadless Packages

(76) Inventors: Ji-hwan Kim, Seoul (KR); Seung-yong Choi, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 12/328,541

(22) Filed: Dec. 4, 2008

(30) Foreign Application Priority Data
Dec. 6, 2007 (KR) 10-2007-0126385

(51) Int. Cl. H01L 23/02

(52) U.S. Cl. 257/686; 257/E23.18

(57) ABSTRACT

Molded leadless packages having improved stacked structures are disclosed. An exemplary molded leadless package includes a die attaching pad, a plurality of leads spaced apart from the die attaching pad at a periphery region of the die attaching pad, a semiconductor chip on the die attaching pad, a plurality of bonding wires electrically connecting the leads to the semiconductor chip, and a sealing member fixedly enclosing the semiconductor chip and the bonding wires while partly exposing an outer surface of each of the leads. The sealing member fills gaps between the die attaching pad and the leads and includes at least one protrusion protruding downward from the die attaching pad and the leads.

### CROSS-REFERENCES TO RELATED APPLICATIONS

This application claims the benefit of Korean Patent Application No. 10-2007-0126385, filed on Dec. 6, 2007, in the Korean Intellectual Property Office, the disclosure of which is incorporated herein in its entirety by reference.

### BACKGROUND OF THE INVENTION

1. Field of Invention

The present disclosure relates to a semiconductor package, and more particularly, to a molded leadless package having a stacked structure with improved reliability and an assembly having stacked molded leadless packages.

2. Description of the Related Art

Generally, a semiconductor package includes a lead frame and a semiconductor chip mounted on the lead frame. A voltage of predetermined value is applied to internal elements of the semiconductor chip. This causes the semiconductor chip to generate heat. For a power semiconductor chip to which a relatively high voltage is applied, the amount of generated heat increases. Therefore, the heat dissipation capability for dissipating the heat generated by the semiconductor chip to an external side has a huge effect on the stability and reliability of the semiconductor package. In order to effectively dissipate the heat generated by the semiconductor chip to the external side, molded leadless packages have been used in a variety of applications. Such molded leadless packages are designed such that a surface of a lead of the lead frame is partly exposed.

For example, U.S. Pat. No. 6,977,431 issued to Oh et al. discloses a stackable semiconductor package and a method of manufacturing the same. Referring to this patent, a second semiconductor package is stacked on a first semiconductor package. The first semiconductor package includes a semiconductor die electrically connected to a lead of a lead frame. The semiconductor die and the internal lead are enclosed by a sealing member such that only a top surface of the internal lead is exposed. Therefore, since the second semiconductor package can be electrically connected to the exposed top surface of the internal lead, the second semiconductor package can be easily stacked on the first semiconductor package. However, if the first and second semiconductor packages are formed in the same structure, it is difficult to stack them.

Meanwhile, U.S. Pat. No. 6,459,148 issued to Chun-Jen, Su et al. discloses a QFN semiconductor package. Referring to this patent, a structure for stacking semiconductor packages having the same structure is disclosed. However, since a semiconductor die is exposed to an external side, it is difficult to obtain a reliable semiconductor stacked structure.

U.S. Pat. No. 6,876,066 filed on Aug. 30, 2001, and issued to Setho Sign Fee et al. discloses package microelectronic devices and methods of forming the same. Referring to this patent, a structure for stacking semiconductor packages formed in the same structure without exposing a semiconductor die is disclosed. However, this structure requires a sealing support and thus the manufacturing process is complicated. In addition, the upper and lower semiconductor packages that are assembled with each other may be separated from each other by an external impact, thereby deteriorating reliability.

Therefore, there is a need for a semiconductor package stacked structure that is reliable and effective.

### BRIEF SUMMARY OF THE INVENTION

One aspect of the present invention provides molded leadless packages having improved stacking structures.

Another aspect of the present invention provides assemblies having molded leadless packages that are effectively and reliably stacked on one another.

### BRIEF DESCRIPTION OF THE DRAWINGS

The above and other features and advantages of the present invention will become more apparent by describing in detail exemplary embodiments thereof with reference to the attached drawings in which:

FIG. 1A is a sectional view of a molded leadless package according to an embodiment of the present invention.

FIG. 1B is a sectional view of a molded leadless package according to another embodiment of the present invention.

FIG. 1C is a sectional view of a molded leadless package according to another embodiment of the present invention.

FIG. 1D is a sectional view of a molded leadless package according to another embodiment of the present invention.

FIG. 2 is a sectional view of a stacked molded leadless package assembly according to another embodiment of the present invention.

FIG. 3 is a sectional view of a stacked molded leadless package assembly according to another embodiment of the present invention.

FIG. 4 is a sectional view of a stacked molded leadless package assembly without a protrusion according to another embodiment of the present invention.

### DETAILED DESCRIPTION OF THE INVENTION

Reference will now be made in detail to exemplary embodiments, examples of which are illustrated in the accompanying drawings. However, exemplary embodiments are not limited to the embodiments illustrated hereinafter, and the embodiments herein are rather introduced to provide an easy and complete understanding of the scope and spirit of example embodiments. In the drawings, the thicknesses of layers and regions are exaggerated for clarity.

Like reference numerals refer to like elements throughout the description. It will be understood that when an element, such as a layer, a region, or a substrate, is referred to as being “on,” “connected to” or “coupled to” another element, it may be directly on, connected or coupled to the other element, or intervening elements may be present. In contrast, when an element is referred to as being “directly on,” “directly connected to” or “directly coupled to” another element or layer, there are no intervening elements or layers present. Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an above and below orientation.

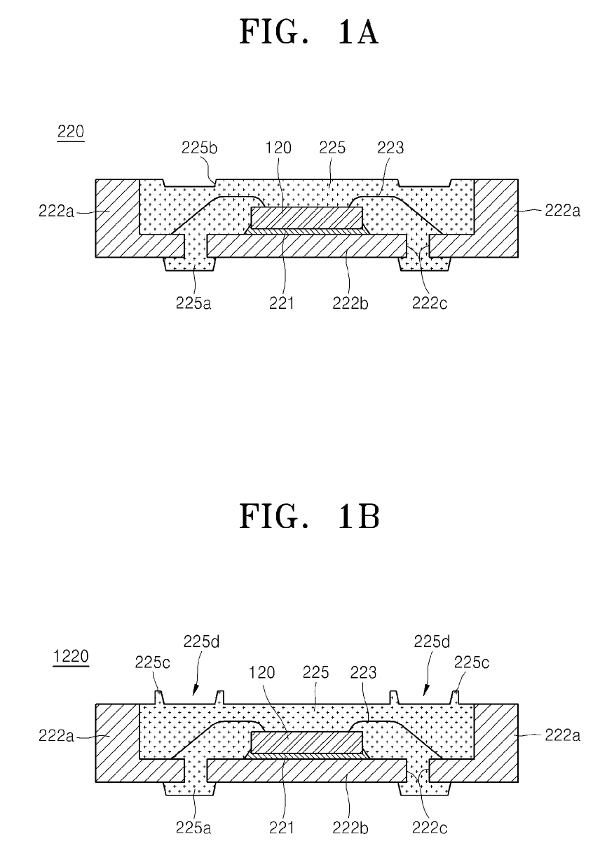

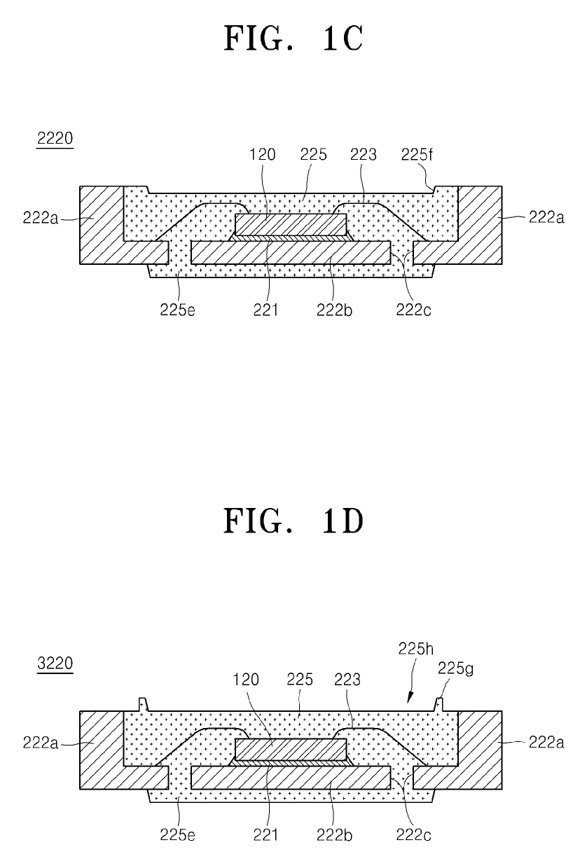

FIG. 1A is a sectional view of a molded leadless package according to an embodiment of the present invention.

Referring to FIG. 1A, a molded leadless package 220 includes a die attaching pad 222b and a plurality of leads 222a that are disposed at a periphery region of the die attaching pad 222b and spaced apart from the die attaching pad 222b by predetermined gaps 222c. A semiconductor chip 120 is mounted on the die attaching pad 222b. At this point, an adhesive layer 221 may be interposed between the die attaching pad 222b and the semiconductor chip 120. The semiconductor chip 120 is electrically connected to the leads 222a by bonding wires 223. Bonding wires 223 may comprise wire bonds, ribbon bonds, tape-automated bonds (“TAB bonds”), conductive clips, and the like.

The leads 222a may include inner leads connected to the bonding wires 223 and outer leads functioning as an external connection terminal of a semiconductor package. In FIG. 1A, the inner leads extend in a horizontal direction and the outer leads are connected to the inner leads and extend in a vertical direction. The leads 222a may be formed through an etching process or a stamping process. The inner leads may be enclosed by a sealing member 225. A portion of a surface of each lead may be exposed. The semiconductor package having the outer leads whose surfaces are partly exposed is referred to as a molded leadless package.

The sealing member 225 fixedly encloses the semiconductor chip 120 and the bonding wires 223 while partly exposing the outer surface of each of the leads 222a and filling the gaps 222c. The sealing member 225 may include protrusions 225a that extend downward through the gaps 222c from undersurfaces of the die attaching pad 222b and leads 222a. The sealing member 225 may be formed of the same material as the protrusions 225a. For example, the sealing member 225 may be formed of an epoxy molding compound (EMC).

The sealing member 225 may be molded in a matrix pattern after attaching a lead frame tape (not shown) on an under surface of a lead frame. However, when the sealing member 225 includes the protrusions 225a as described above, a slotted lead frame tape that is specially prepared is attached on the undersurface of the lead frame and thus it is not appropriate to mold the sealing member in the matrix pattern. Therefore, the sealing member 225 may be molded in a singular pattern.

Semiconductor packages may be classified into sawing type packages and punch type packages in accordance with the fabrication process. The sawing type packages are fabricated by molding a plurality of lead frames on which semiconductor chips are mounted in a single block mold die and cutting the block mold die in a package body/lead frame unit. The punch type packages are fabricated by individually molding lead frames on which the semiconductor chips are mounted in individual mold dies and separating the lead frames through, for example, a punching process. The molded leadless package of this exemplary embodiment may be formed as a punch type package.

The protrusions 225a extend from undersurfaces of the leads 222a near the gaps 222c to an undersurface of the die attaching pad 222b near the gaps. The protrusions 225a may be formed in a circular pillar shape, a polygonal pillar shape, a truncated cone shape, a truncated pyramid shape, a hemispherical shape, or any combination of these and/or other shapes. The circular pillar shape is a solid shape having a uniform circular sectional area. The polygonal pillar shape is a solid shape having a uniform polygonal sectional area. The truncated cone shape means a solid shape whose circular sectional area varies continuously or discontinuously. The truncated pyramid shape is a solid shape whose polygonal sectional area varies continuously or discontinuously. The hemispherical shape is a solid shape of any portion of a sphere, including a half of a sphere. In FIG. 1A, the cross-section of protrusion 225a comprises a truncated cone or pyramid shape. When the protrusions 225a are formed in a truncated cone or pyramid shape, or in a hemispherical shape, the sectional area of the protrusion 225a may be gradually reduced in a direction away from the die attaching pad and the leads.

The protrusions 225a protrude downward from the undersurfaces of the die attaching pad 222b and leads 222a. The protrusions 225a may be symmetrically arranged with respect to the center of the die attaching pad 222b to provide a stable structure.

The sealing member 225 is provided at a top surface with receiving portions that have a shape and size capable of receiving the protrusions 225a of another package. As shown in FIG. 1A, the receiving portions may comprise recesses 225b that are formed on the top surface of the sealing member 225 to receive the protrusions 225a.

The lead 222a may include an exposed top surface located at the same horizontal plane as the top surface of the sealing member 225. The lead 222a may further include an exposed undersurface located at the same horizontal plane as the undersurface of the die attaching pad 222b. The undersurface of the lead 222a may be partly covered by the protrusions 225a. The lead 222a may further include an exposed outer side surface.

FIG. 1B is a sectional view of a molded leadless package according to another embodiment of the present invention.

In FIGS. 1A and 1B, like reference numerals refer to like elements.

Referring to FIG. 1B, receiving portions are formed on the top surface of the sealing member 225. The receiving portions have a shape and size capable of receiving the protrusions 225a of another package. The receiving portion includes sidewalls 225c each protruding from the top surface of the sealing member 225 and defining a cavity 225d having a shape and size capable of receiving the corresponding protrusion 225a.

When the protrusions 225a are formed in any one of the above-listed shapes, the sidewalls 225c may be formed to correspond to the shape of the protrusions 225a and define the cavities 225d receiving the respective protrusions 225a.

As illustrated below in greater detail, the construction of packages 220 and 1220 enables two packages to be stacked upon one another with the protrusions of one package interfitting with the cavities or recesses of another package. In this way, the protrusions and cavities/recesses can align the packages to one another, and set the spacing distance between the packages. It may be appreciated that the recesses 225b or cavities 225d of a package may have substantially the same shape as the protrusions 225a of the package, or may have different shapes, so as to facilitate a particular stacking of different types of package components. It may also be appreciated that, while the shape of a recess/cavity may be different from the shape of a protrusion, these shapes may still be interfitted to a sufficient degree to align two packages to one another, and to provide a desired spacing distance between packages. For example, a protrusion having a polygonal pillar shape with a maximum width may fit within a recess or cavity having a circular pillar shape with an equal or larger width, and a protrusion having a truncated pyramid shape with a maximum base width may fit within a recess or cavity having a truncated cone shape or hemispherical shape with an equal or larger base width. Also, a recess or cavity having a polygonal pillar shape with a minimum width may receive and interfit with a protrusion having a circular pillar shape with an equal or smaller width, Also, a recess or cavity having a polygonal pillar shape with a minimum width may receive and interfit with a protrusion having a circular pillar shape with an equal or smaller width, and a recess or cavity having a truncated pyramid shape with a minimum base width may receive and interfit with a protrusion having a truncated cone or hemispherical shape with an equal or smaller base width. Of course, other combinations of different shapes are possible. Thus, while a recess or cavity may have a shape that is different from that of a protrusion, its shape and size may still be capable of receiving the protrusion.

FIG. 1C is a sectional view of a molded leadless package according to another embodiment of the present invention.

In FIGS. 1A and 1C, like reference numerals refer to like elements. In addition, description of the like elements will be omitted herein.

Referring to FIG. 1C, the sealing member 225 includes a protrusion 225e that extends below the gaps 222c to protrude downward from the undersurfaces of the die attaching pad 222b and the leads 222a. The sealing member 225 may be formed of the same material as the protrusion 225e. For example, the sealing member 225 may be formed of an EMC.

The protrusion 225e may be formed to extend from an undersurface of the lead 222a adjacent to one gap 222c to an undersurface of another lead 222a adjacent to another gap 222c via an undersurface of the die attaching pad 222b. That is, the protrusion 225e may be formed to fully cover the undersurface of the die attaching pad 222b.

The protrusions 225e may be formed in a circular pillar shape, a polygonal pillar shape, a truncated cone shape, a truncated pyramid shape, a hemispherical shape, or any combination of these and/or other shapes, as previously described. When the protrusion 225e is formed in a circular or truncated pyramid shape, or in a hemispherical shape, the sectional area of the protrusion 225e may be gradually reduced in a direction away from the die attaching pad 222b and the leads 222a.

The protrusion 225e protrudes downward from the undersurfaces of the die attaching pad 222b and leads 222a. The protrusion 225e may be symmetrically formed with respect to the center of the die attaching pad 222b to provide a stable structure.

The sealing member 225 is provided at a top surface with a receiving portion that has a shape and size capable of receiving the protrusion 225e of another package. As shown in FIG. 1C, the receiving portions may be a recess 225f concaved on the top surface of the sealing member 225 to receive the protrusion 225e.

FIG. 1D is a sectional view of a molded leadless package according to another embodiment of the present invention.

In FIGS. 1C and 1D, like reference numerals refer to like elements. In addition, description of the like elements will be omitted herein.

Referring to FIG. 1D, a receiving portion is formed on the top surface of the sealing member 225. The receiving portion has a shape and size capable of receiving the protrusion 225e of another package. The receiving portion includes a sidewall 225g protruding from the top surface of the sealing member 225 and defining a cavity 225h having a shape and size capable of receiving the protrusion 225e.

When the protrusion 225e is formed in any one of the above-listed shapes, the sidewall 225g may be formed to correspond to the shape of the protrusion 225e and define the cavity 225h receiving the protrusion 225e.

It may be appreciated that the recess 225f or cavity 225h of a package may have the same shape as the protrusion 225e of the package, or may have different shapes, so as to facilitate a particular stacking of different types of package components. It may also be appreciated that, while the shape of a recess/cavity may be different from the shape of a protrusion, these shapes may still be interfitted to a sufficient degree to align two packages to one another, and to provide a desired spacing distance, as described above. It may also be appreciated that, with appropriate spacing, protrusions 225a of package 220 or 1220 may interfit with recess 225f of package 2220 or cavity 225h of package 3220. It may also be appreciated that a package according to the present invention may comprise protrusions 225a on the one hand, and either of recess 225f or cavity 225h on the other hand.

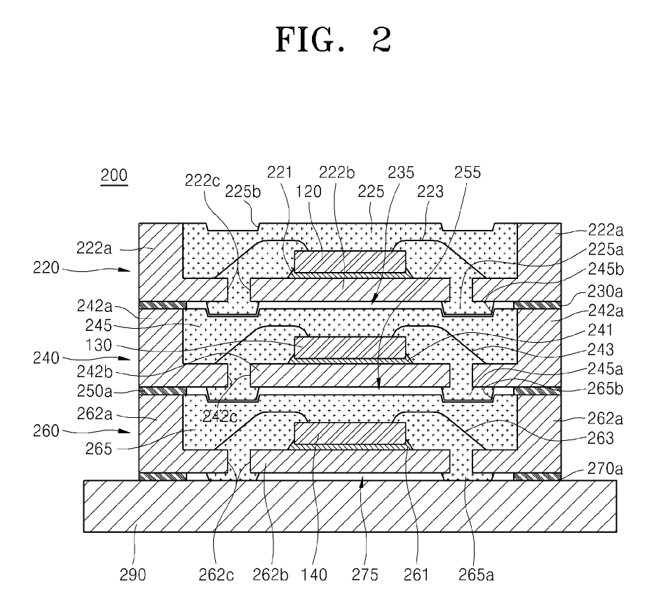

FIG. 2 is a sectional view of a stacked molded leadless package assembly according to another embodiment of the present invention.

Referring to FIG. 2, a molded leadless package 200 of the present embodiment includes a first molded leadless package 220, a second molded leadless package 240, and a third molded leadless package 260.

The first molded leadless package 220 includes a first die attaching pad 222b and a plurality of first leads 222a that are disposed at a periphery region of the first die attaching pad 222b and spaced apart from the first die attaching pad 222b by predetermined first gaps 222c. A first semiconductor chip 120 is mounted on the first die attaching pad 222b. A first adhesive layer 221 may be interposed between the first die attaching pad 222b and the first semiconductor chip 120. A first sealing member 225 fixedly encloses the first semiconductor chip 120 while partly exposing the outer surface of each of the first leads 222a. The sealing member 225 may include first protrusions 225a that extend downward through the first gaps 222c from undersurfaces of the first die attaching pad 222b and first leads 222a. The first protrusions 225a may extend from the undersurface of the first leads 222a near the first gaps 222c to the undersurface of the first die attaching pad 222b near the gaps 222c.

The second molded leadless package 240 includes a second die attaching pad 242b and a plurality of second leads 242a that are disposed at a periphery region of the second die attaching pad 242b and spaced apart from the second die attaching pad 242b by predetermined second gaps 242c. A second semiconductor chip 130 is mounted on the second die attaching pad 242b. A second adhesive layer 241 may be interposed between the second die attaching pad 242b and the second semiconductor chip 130. A second sealing member 245 fixedly encloses the second semiconductor chip 130 while partly exposing the outer surface of each of the second leads 242a. The sealing member 245 may include second protrusions 245a that extend downward through the second gaps 222c from undersurfaces of the second die attaching pad 242b and second leads 242a. The second protrusions 245a may extend from the undersurface of the second leads 242a near the second gaps 242c to the undersurface of the second die attaching pad 242b near the gaps 242c.

The third molded leadless package 260 is also formed to have the same structure as the first and second molded leadless packages 220 and 240. That is, the first, second, and third molded leadless packages 260 are the same as the molded leadless package 220 of FIG. 1A. Therefore, further detailed description of the first, second, and third molded leadless packages 220, 240, and 260 will be omitted herein.

A stacked structure of the first and second molded leadless packages 220 and 240 is as follows. The stacked structure may be identically used for stacking the second and third molded leadless packages 240 and 260 on one another. In FIG. 2, although a structure where three semiconductor packages are stacked on one another is exemplarily illustrated, the present invention is not limited to this embodiment. That is, the stacked structure may be used for any structures for stacking two or more semiconductor chips.

The first and second molded leadless packages 220 and 240 are electrically connected to each other by at least one conductive connecting member 230a. In more detail, each conductive connecting member 230a may be interposed between an undersurface of the first lead 222a of the molded leadless package 220 and a top surface of the second lead 242a of the second molded leadless package 240. Each conductive connecting member 230a functions as a joint for mechanically interconnecting the first and second leadless packages 220 and 240 as well as an electric connector.

Each conductive connecting member 230a may comprise a first conductive solder. As shown in FIG. 2, each first conductive solder may be formed in a film shape. In this case, the first conductive solder may be formed through a wave soldering process. However, the first conductive solder is not limited to the film shape conductive solder, and may be formed in a variety of types. Each conductive connecting member 230a may also comprise a first conductive polymeric adhesive, which may be formed in a variety of shapes, including a film shape.

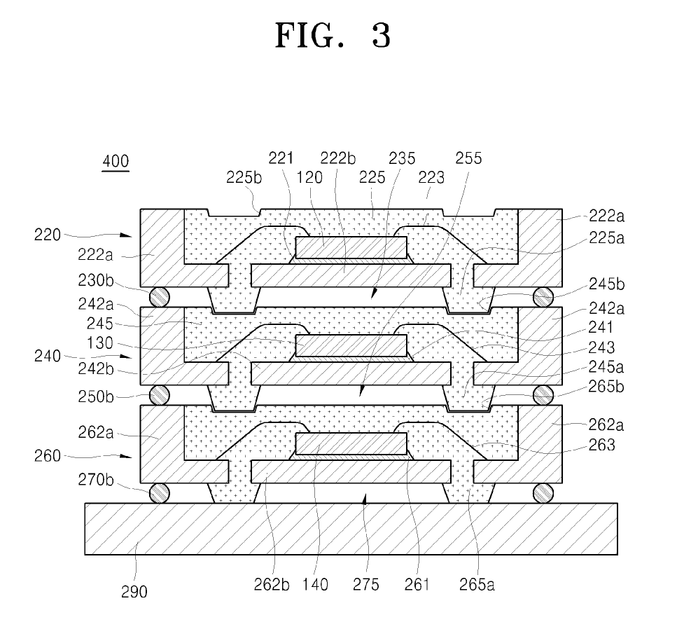

FIG. 3 is a sectional view of a stacked molded leadless package assembly according to another embodiment of the present invention.

Referring to FIG. 3, conductive connecting members 230b formed between the first and second molded leadless packages 220 and 240 comprise conductive solder balls. The solder balls are disposed between the undersurface of the first lead 222a and the top surface of the second lead 242a to mechanically and electrically connect the first molded leadless package 220 to the second molded leadless package 240.

Referring again to FIG. 2, a gap between the first protrusion 225a and the second recess 245b can be adjusted by adjusting a height of the conductive connecting member 230a. For example, the height of the conductive connecting member 230a may be set such that an undersurface of the first protrusion 225a contacts a bottom surface of the second recess 245b. Alternatively, the height of the conductive connecting member 230a may be set such that the undersurface of the first protrusion 225a is spaced apart from the bottom surface of the second recess 245b. In this case, the first protrusion 225a may be still received in the second recess 245b. A height of the conductive connecting member 230b may be identically set according to the height of the conductive connecting member 230a of FIG. 2.

As the first protrusion 225a of the first molded leadless package 220 is received in the second recess 245b of the second molded leadless package 240, the height of connecting members 230a and 230b can be reliably controlled. Controlling the height of members 230a and 230b enables the thermal stress and strain on these components to be controlled and reduced, and, in turn, the fatigue lifetimes and the reliability of the conductive connecting members 230a and 230b can be enhanced.

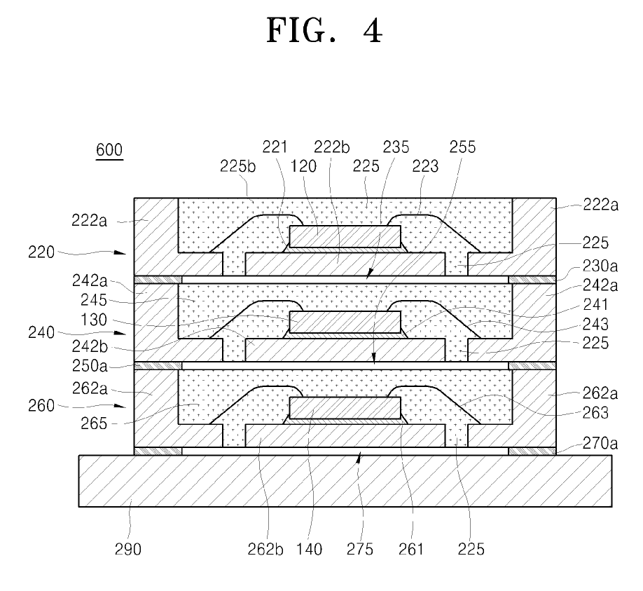

FIG. 4 is a sectional view of a stacked molded leadless package assembly without a protrusion according to another embodiment of the present invention.

Referring to FIG. 4, the mechanical connection between the packages is realized by conductive connecting members 230a, 250a, and 270a. However, since the protrusion and recess that are illustrated in FIGS. 2 and 3 are not provided, the fatigue life of the conductive connecting members 230a, 250a, and 270a may be reduced since a proper height for stress and strain reduction may not be obtained. That is, the fatigue life of the conductive connecting members 230a, 250a, and 270a may increase as the protrusion of an upper semiconductor package is received or inserted in the recess of a lower semiconductor package. Furthermore, the protrusion and recess make it easy to align the semiconductor packages when stacking them.

Referring again to FIGS. 2 and 3, the first protrusions 225a protrude downward from the first die attaching pad and the first lead, and are symmetrically arranged with respect to the center of the first die attaching pad to provide a stable stacked structure of the first and second molded leadless packages 220 and 240. The protrusions 225a may be formed in any one of the above-listed shapes. The second recess 245b receiving the corresponding first protrusion 225a may be formed in a shape corresponding to a shape of the corresponding first protrusion 225a.

Molded leadless package 260 is attached to an interconnect substrate 290. Substrate 290 and packages 220, 240, and 260 may collectively comprise an electrical system or a part of an electrical system. Empty spaces 235 and 255 are formed between the first, second, and third molded leadless packages 220, 240, and 260, and an empty space 275 is formed between package 260 and an interconnect substrate 290. Empty spaces 235, 255, 275 may be filled with second conductive solders or adhesive layers.

Although the protrusions and recesses illustrated in FIGS. 2 and 3 have the same structure as described with respect to FIG. 1A, the present invention is not limited to this configuration. That is, the protrusions and recesses of FIGS. 2 and 3 may be formed to have the same structure as described with respect to FIGS. 1B, 1C, or 1D, and variations thereof as described above.

According to the above-described embodiments, the semiconductor packages formed in the same structure as each other can be effectively aligned and stacked on one another.

Since the height of the conductive connecting member can be properly maintained by the protrusion, the fatigue life of the conductive connecting member can be increased.

Furthermore, as the protrusion of the upper semiconductor package is received or inserted in the recess of the lower semiconductor package, the stacked structure of the semiconductor packages can be reliably realized.

The packages described above can be used in electrical assemblies including circuit boards with the packages mounted thereon. They may also be used in systems such as phones, computers, etc.

Any recitation of “a”, “an”, and “the” is intended to mean one or more unless specifically indicated to the contrary.

The terms and expressions which have been employed herein are used as terms of description and not of limitation, and there is no intention in the use of such terms and expressions of excluding equivalents of the features shown and described, it being recognized that various modifications are possible within the scope of the invention claimed.

Moreover, one or more features of one or more embodiments of the invention may be combined with one or more features of other embodiments of the invention without departing from the scope of the invention.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A molded leadless package comprising:
a die attaching pad;
a plurality of leads spaced apart from the die attaching pad at a periphery region of the die attaching pad;
a semiconductor chip on the die attaching pad;
a plurality of bonding wires electrically connecting the leads to the semiconductor chip; and
a sealing member fixedly enclosing the semiconductor chip and the bonding wires while partly exposing an outer surface of each of the leads,
wherein the sealing member fills gaps between the die attaching pad and the leads and comprises one or more protrusions, each protrusion protruding downward from the die attaching pad and the leads.

2. The molded leadless package of claim 1, wherein the sealing member is provided at a top surface with a receiving portion having a shape and size capable of receiving a protrusion.

3. The molded leadless package of claim 2, wherein the receiving portion comprises a recess formed on the top surface of the sealing member and having a shape and size capable of receiving the protrusion.

4. The molded leadless package of claim 2, wherein the receiving portion includes a sidewall protruding upward from the top surface of the sealing member and defining a cavity having a shape and size capable of receiving the protrusion.

5. The molded leadless package of claim 1, wherein at least one protrusion extends from an undersurface of the lead near the gap to an undersurface of the die attaching pad near the gap.

6. The molded leadless package of claim 1, wherein the protrusion fully covers an undersurface of the die attaching pad.

7. The molded leadless package of claim 1, wherein at least one protrusion is formed in a circular pillar shape, a polygonal pillar shape, a truncated cone shape, a truncated pyramid shape, or a hemispherical shape.

8. The molded leadless package of claim 1, wherein at least one protrusion is symmetrically arranged with respect to the center of the die attaching pad.

9. The molded leadless package of claim 1, wherein at least one protrusion is formed of the same material as the sealing member.

10. The molded leadless package of claim 1, wherein at least one protrusion and the sealing member are formed of an epoxy molding compound.

11. The molded leadless package of claim 1, wherein the lead comprises an exposed top surface located at the same horizontal plane as a top surface of the sealing member and an exposed undersurface located at the same horizontal plane as an undersurface of the die attaching pad.

12. The molded leadless package of claim 1, wherein each of the leads comprises an inner lead connected to the bonding wire and extending in a horizontal direction and an outer lead connected to the inner lead and extending in a vertical direction.

13. A stacked molded leadless package assembly comprising:
a first molded leadless package; and
a second molded leadless package assembly on which the first molded leadless package is stacked;
wherein the first molded leadless package comprises:
a first die attaching pad;
a plurality of first leads spaced apart from the first die attaching pad at a periphery region of the first die attaching pad;
a first semiconductor chip on the die attaching pad;
a plurality of first bonding wires electrically connecting the first leads to the first semiconductor chip; and
a first sealing member fixedly enclosing the first semiconductor chip and the first bonding wires while partly exposing an outer surface of each of the first leads, filling first gaps between the first die attaching pad and the first leads, and comprising at least one protrusion protruding downward from the first die attaching pad and the first leads, and
the second molded leadless package comprises:
a second die attaching pad;
a plurality of second leads spaced apart from the second die attaching pad at a periphery region of the second die attaching pad;
a second semiconductor chip on the die attaching pad;
a plurality of second bonding wires electrically connecting the second leads to the second semiconductor chip; and
a second sealing member fixedly enclosing the second semiconductor chip and the second bonding wires while partly exposing an outer surface of each of the second leads, filling second gaps between the second die attaching pad and the second leads, and provided at a top surface with a receiving portion for fixedly receiving the protrusion.

14. The stacked molded leadless package assembly of claim 13, further comprising a conductive connecting member between undersurfaces of the first leads and top surfaces of the second leads.

15. The stacked molded leadless package assembly of claim 14, wherein the conductive connecting member comprises a conductive solder.

16. The stacked molded leadless package assembly of claim 15, wherein the conductive solder is formed in a film shape or a ball shape.

17. The stacked molded leadless package assembly of claim 14, wherein a height of the conductive connecting member is set such that an under surface of the protrusion contacts a bottom surface of the receiving portion.

18. The stacked molded leadless package assembly of claim 14, wherein a height of the conductive connecting member is set such that an undersurface of the protrusion is spaced apart from a bottom surface of the receiving portion.

19. The stacked molded leadless package assembly of claim 13, further comprising an adhesive layer between the first and second molded leadless packages.

20. The stacked molded leadless package assembly of claim 13, further comprising a conductive solder between the first and second molded leadless packages.

21. A system comprising an interconnect substrate and the stacked molded leadless package assembly of claim 13 attached to the interconnect substrate.
